(19) United States
(12) Patent Application Publication
(10) Pub. No.: US 2006/0175645 A1
(43) Pub. Date: Aug. 10, 2006

(54) Semiconductor device and its manufacturing method

(76) Inventors: Hiroyuki Kanaya, Yokohama-shi (JP); Iwao Kunishima, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/373,308

(22) Filed: Mar. 13, 2006

Related U.S. Application Data
(62) Division of application No. 10/827,331, filed on Apr. 20, 2004.

(30) Foreign Application Priority Data
May 22, 2003 (JP) 2003-144869

(51) Int. Cl. H01L 29/94

(52) U.S. Cl. 257/295

(57) ABSTRACT

A semiconductor device includes a switching element formed on a semiconductor substrate, a first interconnect layer formed on the semiconductor substrate and having a first wiring connected to one terminal of the switching element, a ferroelectric capacitor formed on the first interconnect layer and having a first electrode connected to the one terminal of the switching element via the first wiring, a first protective film formed on the ferroelectric capacitor and the first interconnect layer, a second interconnect layer formed on the first protective film and having a second wiring connected to a second electrode of the ferroelectric capacitor and a first interlayer insulating film having a dielectric constant of 4 or more, and a third interconnect layer formed on the second interconnect layer and having a second interlayer insulating film with a dielectric constant of less than 4.

### CROSS-REFERENCE TO RELATED APPLICATIONS

This application is a divisional of and claims the benefit of priority from U.S. Ser. No. 10/827,331, filed Apr. 20, 2004, and is based upon and claims the benefit of priority from the prior Japanese Patent Application No. 2003-144869, filed May 22, 2003, the entire contents of which are incorporated herein by reference.

### BACKGROUND OF THE INVENTION

1. Field of the Invention

The present invention relates to a semiconductor device having a ferroelectric memory, and in particular, to a semiconductor device comprising a ferroelectric capacitor as a storage element, as well as to a manufacturing method for this semiconductor device.

2. Description of the Related Art

FeRAMs (Ferroelectric Random Access Memories) using a ferroelectric capacitor as a storage element are widely used as nonvolatile memories. If an FeRAM is manufactured using a multilayer interconnect, it is important to suppress damage to the ferroelectric capacitor during the steps of manufacturing the multilayer interconnect after the ferroelectric capacitor has been formed. Further, owing to the increased degree of integration and improved performance of recent LSIs, the interconnect capacitance of the multilayer interconnect must be reduced.

On the other hand, it is expected that the interconnect capacitance of a multilayer metal interconnect can be reduced by using a film having a lower dielectric constant (hereinafter referred to as a “low-k film”) as an interlayer insulating film used to bury the multilayer interconnect.

Further, a method has been proposed which comprises using a low-k film as an interlayer insulating film to manufacture a semiconductor device containing a ferroelectric memory (refer to Jpn. Pat. Appln. KOKAI Pub. No. 2001-244426).

However, the inventors' experiments indicate that if a low-k film is used as an interlayer insulating film containing a ferroelectric capacitor, it may be released because of oxygen annealing or the like carried out during the manufacturing process in order to improve the characteristics of the ferroelectric capacitor. If the low-k film is released, the FeRAM does not operate correctly. As a result, yield may decrease sharply, increasing manufacturing costs.

### BRIEF SUMMARY OF THE INVENTION

According to a first aspect of the present invention, there is provided a semiconductor device including: a switching element formed on a semiconductor substrate; a first interconnect layer formed on the semiconductor substrate and having a first wiring connected to one terminal of the switching element; a ferroelectric capacitor formed on the first interconnect layer and having a first electrode connected to the one terminal of the switching element via the first wiring; a first protective film formed on the ferroelectric capacitor and the first interconnect layer; a second interconnect layer formed on the first protective film and having a second wiring connected to a second electrode of the ferroelectric capacitor and a first interlayer insulating film having a dielectric constant of 4 or more; and a third interconnect layer including at least one layer formed on the second interconnect layer, the third interconnect layer having a third wiring connected to the second wiring and a second interlayer insulating film having a dielectric constant of less than 4.

According to a second aspect of the present invention, there is provided a semiconductor device including: a switching element formed on a semiconductor substrate; a first interconnect layer formed on the semiconductor substrate and having a first wiring connected to one terminal of the switching element; a ferroelectric capacitor formed on the first interconnect layer and having a first electrode and a second electrode; a first protective film formed on the ferroelectric capacitor and the first interconnect layer; a second interconnect layer formed on the first protective film, the second interconnect layer including a second wiring having a first via plug connected to the first wiring and a second via plug connected to the first electrode of the ferroelectric capacitor, a third wiring having a third via plug connected to the second electrode of the ferroelectric capacitor, and a first interlayer insulating film having a dielectric constant of 4 or more; and a third interconnect layer including at least one layer formed on the second interconnect layer, the third interconnect layer having a fourth wiring connected to the third wiring and a second interlayer insulating film having a dielectric constant of less than 4.

According to a third aspect of the present invention, there is provided a manufacturing method for a semiconductor device including: forming a switching element on a semiconductor substrate; forming, on the semiconductor substrate, a first interconnect layer which has a first wiring connected to one terminal of the switching element; forming, on the first interconnect layer, a ferroelectric capacitor which has a first electrode connected to the one terminal of the switching element via the first wiring; forming a first protective film on the ferroelectric capacitor and the first interconnect layer; forming, on the first protective film, a second interconnect layer which has a second wiring connected to a second electrode of the ferroelectric capacitor and a first interlayer insulating film with a dielectric constant of 4 or more; and forming, on the second interconnect layer, a third interconnect layer which has a third wiring connected to the second wiring and a second interlayer insulating film with a dielectric constant of less than 4.

### BRIEF DESCRIPTION OF THE SEVERAL VIEWS OF THE DRAWING

FIG. 1 is a sectional view showing the structure of an FeRAM according to a first embodiment of the present invention;

FIG. 2 is a sectional view illustrating a manufacturing process for an FeRAM having the structure shown in FIG. 1;

FIG. 3 is a sectional view illustrating a manufacturing process continued from FIG. 2;

FIG. 4 is a sectional view illustrating a manufacturing process continued from FIG. 3;

FIG. 5 is a sectional view illustrating a manufacturing process continued from FIG. 4;

FIG. 6 is a graph showing the relationship between the dielectric constant of an interlayer film and the polarization capacitance of a capacitor observed if an interlayer insulating film is formed of dielectric materials of the same dielectric constant;

FIG. 7 is a sectional view showing the structure of an FeRAM according to a second embodiment of the present invention;

FIG. 8 is a sectional view illustrating a manufacturing process for an FeRAM having the structure shown in FIG. 7;

FIG. 9 is a sectional view illustrating a manufacturing process continued from FIG. 8;

FIG. 10 is a sectional view showing the structure of an FeRAM according to a third embodiment of the present invention;

FIG. 11 is a sectional view showing the structure of an FeRAM according to a fourth embodiment of the present invention;

FIG. 12 is a sectional view showing the structure of an FeRAM according to a fifth embodiment of the present invention; and

FIG. 13 is a sectional view showing the structure of an FeRAM according to a sixth embodiment of the present invention.

### DETAILED DESCRIPTION OF THE INVENTION

Embodiments of the present invention will be described below with reference to the drawings.

### First Embodiment

FIG. 1 is a sectional view showing the structure of a memory cell of an FeRAM according to a first embodiment of the present invention.

An element area 2 is formed on a semiconductor substrate 1 (for example, an Si substrate). A switching transistor Tr is formed on the element area 2 and is composed of a gate electrode 3b formed via a gate insulating film 3a and source/drain areas (S/D). The switching transistor Tr is covered with an interlayer insulating film 4. The interlayer insulating film 4 is composed of, for example, SiO₂. A contact plug 5 is formed on one terminal of the switching transistor Tr, i.e. one of the source/drain areas (S/D) so as to penetrate the interlayer insulating film 4. The upper end of the contact plug 5 is connected to a lower electrode 6b of a ferroelectric capacitor 6 formed on the interlayer insulating film 4.

A ferroelectric capacitor 6 constituting an FeRAM cell has a COP (Capacitor On Plug) structure as shown in FIG. 1. However, the present invention is not limited to this structure but the lower electrode 6b may have an offset structure. Then, an electrode lead-out may be formed so as to extend from the lower electrode 6b toward an upper electrode 6a. This will be described later in detail.

In FIG. 1, the ferroelectric capacitor 6 is composed of the upper electrode 6a, the lower electrode 6b, and a ferroelectric film 6c. The upper electrode 6a has a stacked structure of, for example, Pt/SrRuO₃. The ferroelectric film 6c is composed of, for example, PbZrₓTi₁₋ₓO₃ (hereinafter referred to as “PZT”). The lower electrode 6b has a stacked structure of, for example, SrRuO₃/(Ti)/Pt/Ti/IrOₓ/Ir/Ti. The lower electrode 6b of the ferroelectric capacitor 6 is connected to the source/drain area (S/D) via the contact plug 5 so as to form the COP structure.

A protective film 7 is formed on a surface of the ferroelectric capacitor 6 and on a surface of the interlayer insulating film 4 in order to prevent the ferroelectric capacitor 6 from being damaged during the subsequent steps of manufacturing a multilayer interconnect layer. The protective film 7 is composed of, for example, aluminum oxide with a thickness of 70 [nm].

A first metal interconnect layer is formed on the protective film 7. In this respect, an interconnect layer in the present invention includes the interlayer insulating film and an interconnect formed on the interlayer insulating film. A plasma SiO₂ (P—SiO₂) interlayer insulating film 8 is formed on the protective film 7. The P—SiO₂ interlayer insulating film 8 is composed of, for example, TEOS (Tetra-Ethyl Orso Silicate) with a dielectric constant of 4.1.

A via hole is formed in the P—SiO₂ interlayer insulating film 8 so as to lead to the upper electrode 6a of the ferroelectric capacitor 6. A barrier metal (with a thickness of, for example, 50 [nm]) composed of TiN (not shown) is formed on an inner wall surface of the via hole. An Al via plug 9 is buried in this via hole. An Al interconnect 10 is formed on the P—SiO₂ interlayer insulating film 8 so as to connect to the Al via plug 9.

A second metal interconnect layer is formed on the Al interconnect 10. That is, a low-k interlayer insulating film 11 is formed on the Al interconnect 10. The low-k means a film of a low dielectric constant, e.g. a film composed of a material with a dielectric constant of less than 4. The low-k interlayer insulating film 11 is composed of, for example, SiOₓC_{y}, which has a dielectric constant of 2.7. Alternatively, the low-k material may be an organic film containing, for example, a CₓH_{y} structure.

A via plug 12 is buried in the low-k interlayer insulating film 11 and is connected to the Al interconnect 10. The via plug 12 is composed of, for example, tungsten (W). An Al interconnect 13 is formed on the low-k interlayer insulating film 11 so as to connect to the via plug 12.

A third metal interconnect layer is formed on the Al interconnect 13. That is, a low-k interlayer insulating film 14 is formed on the Al interconnect 13. The low-k interlayer insulating film 14 is composed of, for example, SiOₓC_{y}, which has a dielectric constant of 2.7 as described above.

A via plug 15 composed of, for example, W is buried in the low-k interlayer insulating film 14 and is connected to the Al interconnect 13. The via plug 15 is composed of, for example, W. An Al interconnect 16 is formed on the low-k interlayer insulating film 14 so as to connect to the via plug 15.

A low-k interlayer insulating film 17 is formed on the Al interconnect 16. The low-k interlayer insulating film 17 is composed of, for example, SiOₓC_{y}, which has a dielectric constant of 2.7 as described above.

A via plug 18 composed of, for example, W is buried in the low-k interlayer insulating film 17 and is connected to the Al interconnect 16. The via plug 15 is composed of, for example, W.

An electrode pad 19 composed of, for example, Al is formed on the low-k interlayer insulating film 17 so as to connect to the via plug 18.

A passivation film 20 is deposited on the electrode pad 19 and the low-k interlayer insulating film 17. The passivation film 20 is composed of, for example, SiOₓH_{y}. A contact hole for an electrode pad 19 is formed in the passivation film 20.

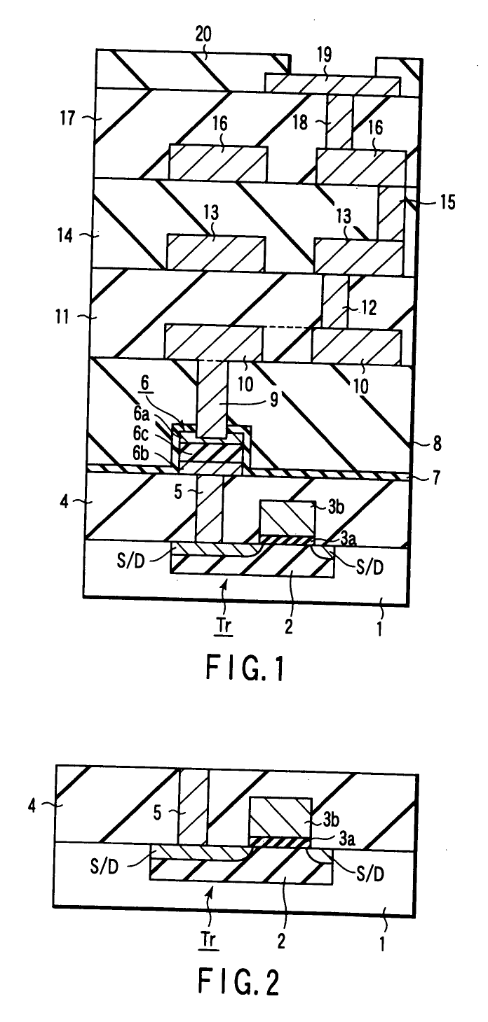

With reference to FIGS. 2, 3, 4, and 5, description will be given of a manufacturing process for the FeRAM having the memory cell structure shown FIG. 1.

In FIG. 2, the element area 2 is formed on the semiconductor substrate 1 (for example, an Si substrate). The switching transistor Tr is formed on in the element area 2. That is, the gate electrode 3b composed of, for example, polysilicon is formed on the element area 2 via the gate insulating film 3a. The source/drain areas (S/D) are formed at the respective sides of the gate electrode 3b. These areas S/D are formed by injecting, for example, impurity ions into the element area 2.

The switching transistor Tr is covered with the interlayer insulating film 4. Before the surface of the interlayer insulating film 4 is flattened by CMP (Chemical Mechanical Polishing), the contact hole leading to the area S/D that is one of the terminals of the switching transistor Tr is opened by, for example, a dry etching method. The contact plug 5 composed of, for example, W is buried in the contact hole and is connected to the area S/D. In this state, the surface of the interlayer insulating film 4 is flattened by CMP together with the contact plug 5.

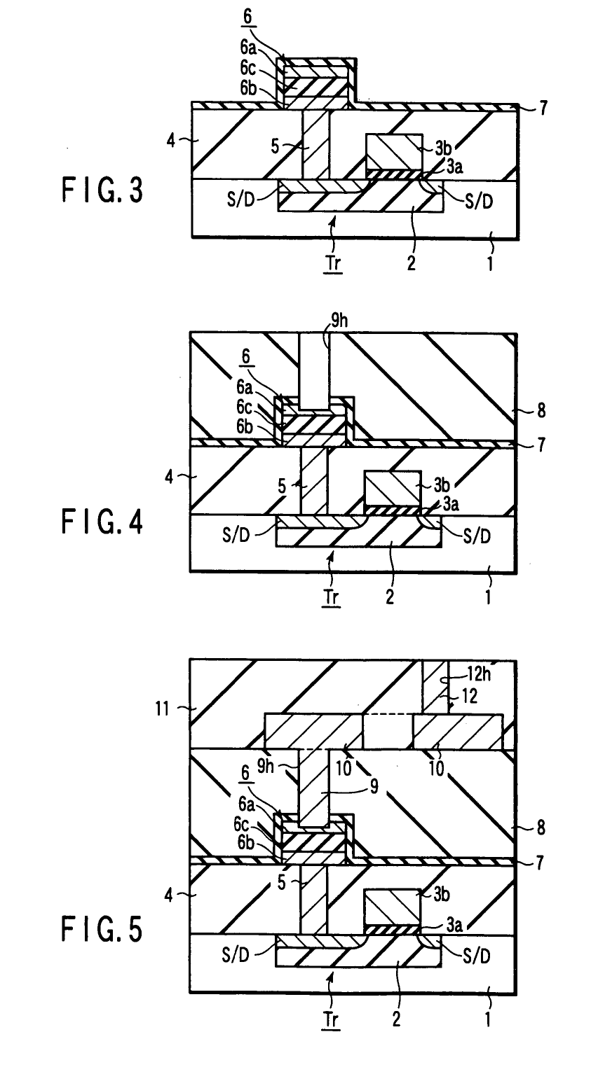

Then, as shown in FIG. 3, a conductive material as the lower electrode 6b of the ferroelectric capacitor 6 is stacked on the interlayer insulating film 4 so as to connect to the contact plug 5. Furthermore, a ferroelectric material as the ferroelectric film 6c and a conductive material as the upper electrode 6a are sequentially stacked. Then, the ferroelectric capacitor 6 shaped as shown in FIG. 3 is formed by, for example, an RIE (Reactive Ion Etching) method.

The protective film 7 composed of, for example, aluminum oxide with a thickness of 70 [nm] is formed, by a sputtering or ALD (Atomic Layer Deposition) method, on the surface of the ferroelectric capacitor 6 and on the surface of the interlayer insulating film 4 in order to prevent the ferroelectric capacitor 6 from being damaged during the subsequent steps of manufacturing a multilayer interconnect layer.

Then, as shown in FIG. 4, the P—SiO₂ interlayer insulating film 8 is formed on the protective film 7 by a plasma CVD method at a temperature of 380 to 400° C. The surface of the P—SiO₂ interlayer insulating film 8 is flattened by CMP. Subsequently, the via hole 9h, leading to the upper electrode 6a, is formed in the P—SiO₂ interlayer insulating film 8 by, for example, a dry etching method. A resist film is formed on the P—SiO₂ interlayer insulating film 8 subjected to the CMP process and is then patterned by a photolithography method. Then, the patterned resist film is used as an etching mask to open the via hole 9h, shaped as shown in FIG. 4. At this time, the via hole is formed in the upper electrode 6a so as to be partly over-etched as required.

In this state, to recover the ferroelectric film 6c of the ferroelectric capacitor 6 damaged by the processing of the ferroelectric capacitor 6, the formation of the protective film 7, the formation of the P-iO₂ interlayer insulating film 8, the opening of the via hole 9h, and the like, the substrate is subjected to oxygen annealing at a temperature of 600° C. for one hour.

Then, as shown in FIG. 5, TiN barrier metal (with a thickness of, for example, 50 [nm]) is formed (not shown) in the via hole 9h as required. Furthermore, a liner film (not shown) is formed on the surface of the barrier metal. Then, the AL via plug 9 is formed in the via hole 9h by, for example, a reflow method.

Subsequently, the surfaces of the P—SiO₂ interlayer insulating film 8 and Al via plug 9 are flattened by the CMP method. The Al interconnect 10 is formed on the P—SiO₂ interlayer insulating film 8 so as to connect to the Al via plug 9. The Al interconnect 10 is formed by, for example, using the RIE method to pattern the Al film formed all over the top surface of the P—SiO₂ interlayer insulating film 8.

For example, SiOₓC_{y}, which has a dielectric constant of 2.7, is used to form the low-k interlayer insulating film 11 on the surfaces of the Al interconnect 10 and P—SiO₂ interlayer insulating film 8 by the plasma CVD method at a temperature of 350° C. Then, for example, the dry etching method is used to form a via hole 12h leading to the Al interconnect 10, in the low-k interlayer insulating film 11, flattened by the CMP method. Then, tungsten (W) is deposited as a via plug material to form the via plug 12. The surfaces of the low-k interlayer insulating film 11 and via plug 12 are flattened by the CMP method.

The Al interconnect 13 and low-k interlayer insulating film 14 in a second layer and the Al interconnect 16 and low-k interlayer insulating film 17 in a third layer are formed similarly to the Al interconnect 10 in the previously described first layer. In this manner, an FeRAM is formed which has the structure shown in FIG. 1. The low-k interlayer insulating film 14 and the low-k interlayer insulating film 17 may both be formed of SiOₓC_{y}, which has a dielectric constant of 2.7, or an organic film, e.g. CₓH_{y}.

In connection with stress that may occur in the semiconductor substrate 1 owing to a difference in thermal expansion coefficient between the semiconductor substrate 1 and the interlayer film material of a multilayer interconnect layer formed on the semiconductor substrate 1, the FeRAM configured as described above undergoes a lower stress than one obtained by forming all interlayer insulating films of P—SiO₂, which has a dielectric constant of 4.1.

If a low-k film is used as the interlayer insulating film formed on the protective film 7, it is often released upon oxygen annealing carried out after a contact hole has been formed in the upper electrode 6. This reduces yield. By providing P—SiO₂ (which has a dielectric constant of at least 4) on the protective film 7 as with the present structure, this film release problem can be suppressed.

Further, the temperature (for example, 350 to 380° C.) at which the low-k interlayer insulating films 11, 14, and 17 are formed is lower than the temperature (for example, 380 to 400° C.) at which the P—SiO₂ interlayer insulating film 8 is formed. This reduces damage to the ferroelectric capacitor 6 caused by hydrogen radicals generated by material gases for the interlayer insulating films 11, 14, and 17 during their deposition.

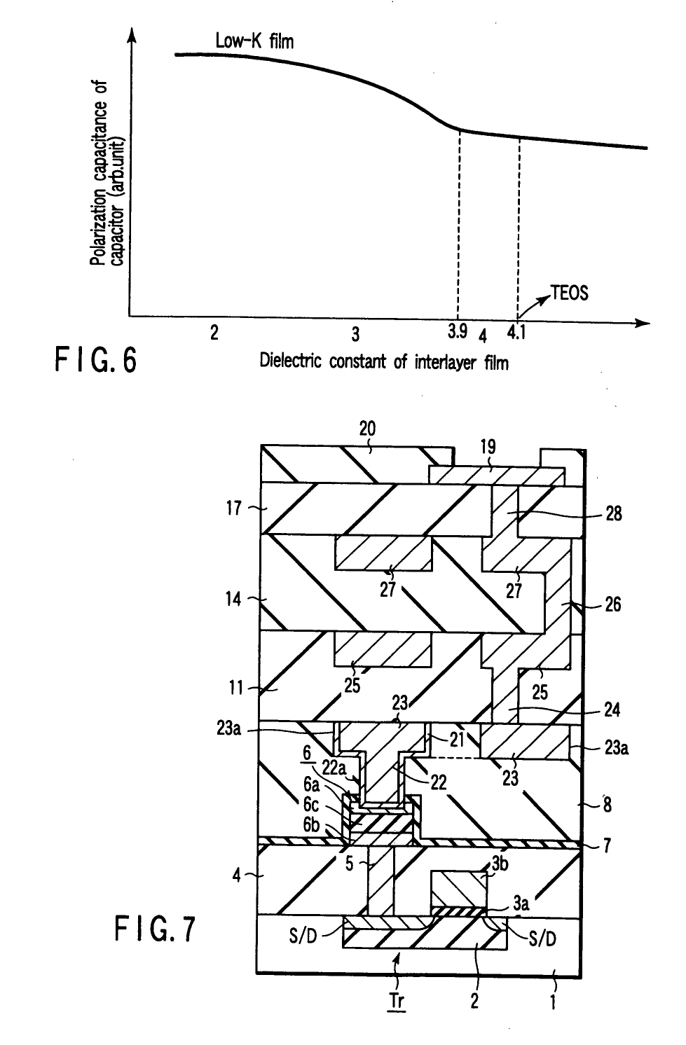

Furthermore, in the FeRAM generated as described above, the ferroelectric capacitor 6 has an improved polarization capacitance. FIG. 6 is a graph showing the relationship between a dielectric constant of an interlayer film and the polarization capacitance of the capacitor observed if in the same configuration as that of the FeRAM generated as described above, the interlayer insulating films 11, 14, and 17 are formed of the same material of the same dielectric constant. This figure indicates that the polarization capacitance of the ferroelectric capacitor 6 increases with decreasing dielectric constant of the interlayer insulating films 11, 14, and 17.

In terms of measured values, for the FeRAM generated as described above and configured as shown in FIG. 1, the ferroelectric capacitor 6 has a polarization capacitance of 35 to 36 [μC/cm²]. In contrast, if all the interlayer insulating films 11, 14, and 17 are formed of, for example, P—SiO₂, which has a dielectric constant of 4.1, the ferroelectric capacitor has a polarization capacitance of 30 to 33 [μC/cm²]. Thus, the ferroelectric capacitor 6 configured as shown in FIG. 1 has a definitely improved polarization capacitance.

As described above in detail, in the first embodiment, the interlayer insulating film contacted with the protective film 7 is formed as the P—SiO₂ interlayer insulating film 8. The interlayer insulating film formed on the P-iO₂ interlayer insulating film 8 is formed as the low-k interlayer insulating film 11.

Thus, according to the present embodiment, it is possible to reduce stress that may occur in the semiconductor substrate 1. It is also possible to improve the polarization capacitance of the ferroelectric capacitor 6. Furthermore, the release of the interlayer insulating film can be prevented compared to the formation of a low-k interlayer insulating film on the protective film 7.

Further, the Al interconnect 10 is formed by using the RIE method, thereby the characteristic of the ferroelectric capacitor 6 has been improved.

Furthermore, the Al interconnects 13 and 16 are formed by using the RIE method, thereby the characteristic of the ferroelectric capacitor 6 has been improved. And, FeRAM has the low-k interlayer insulating film and interconnect formed by the RIE method, thereby the characteristic of the ferroelectric capacitor 6 has been improved.

### Second Embodiment

The embodiment shown in FIG. 1 has been described as an example in which the multilayer interconnect is formed of Al interconnects. In a second embodiment, described below, an FeRAM is constructed using Cu interconnects in a multilayer interconnect.

FIG. 7 is a sectional view showing the structure of an FeRAM according to the second embodiment of the present invention. In this figure, the same portions as those in FIG. 1 are denoted by the same reference symbols. Their description will is omitted.

A first metal interconnect layer is formed on the protective film 7. Specifically, the plasma SiO₂ (P—SiO₂) interlayer insulating film 8 is formed on the protective film 7. The P—SiO₂ interlayer insulating film 8 is composed of, for example, TEOS (Tetra-Ethy; Orso Silicate), which has a dielectric constant of 4.1.

A via hole 22a and an interconnect groove 23a are formed in the P—SiO₂ interlayer insulating film 8 so as to lead to the upper electrode 6a of the ferroelectric capacitor 6. Barrier metal 21 composed of TiN (with a thickness of, for example, 100 [nm]) is formed in the via hole 22a and interconnect groove 23a. A liner film (not shown) is formed on the surface of the barrier metal 21 as required. Then, a Cu via plug 22 is formed in the via hole 22a, with a Cu interconnect 23 formed in the interconnect groove 23a. Cu is simultaneously buried in a groove formed in the surface of the upper electrode 6a of the ferroelectric capacitor 6 by overetching. In this case, to suppress damage to the ferroelectric capacitor 6 owing to the deposition of Cu, the upper electrode 6a may be formed of, for example, IrOₓ/SrRuO₃, SrRuO₃, or Sr(Ru₍₁₋ₓ₎Ti₍ₓ₎)O₃.

In this manner, a Cu interconnect 23 is formed on the P—SiO₂ interlayer insulating film 8 so as to connect to the Cu via plug 22.

A second metal interconnect layer is formed on the Cu interconnect 23. Specifically, the low-k interlayer insulating film 11 is formed on the Cu interconnect 23. The Cu via plug 24 is formed in the low-k interlayer insulating film 11 and is connected to the Cu interconnect 23. Furthermore, a Cu interconnect 25 is formed in the low-k interlayer insulating film 11 so as to connect to the Cu via plug 24.

A third metal interconnect layer is formed on the Cu interconnect 25. Specifically, the low-k interlayer insulating film 14 is formed on the Cu interconnect 25. A Cu via plug 26 is formed in the low-k interlayer insulating film 14 and is connected to the Cu interconnect 25. Furthermore, a Cu interconnect 27 is formed in the low-k interlayer insulating film 11 so as to connect to the Cu via plug 26.

The low-k interlayer insulating film 17 is formed on the Cu interconnect 27. A Cu via plug 28 connected to the Cu interconnect 27 is formed in the low-k interlayer insulating film 17. The Cu via plug 28 is connected to the electrode pad 19, formed on the surface of the low-k interlayer insulating film 17. The resulting top surface of the substrate is entirely covered with a passivation film 20.

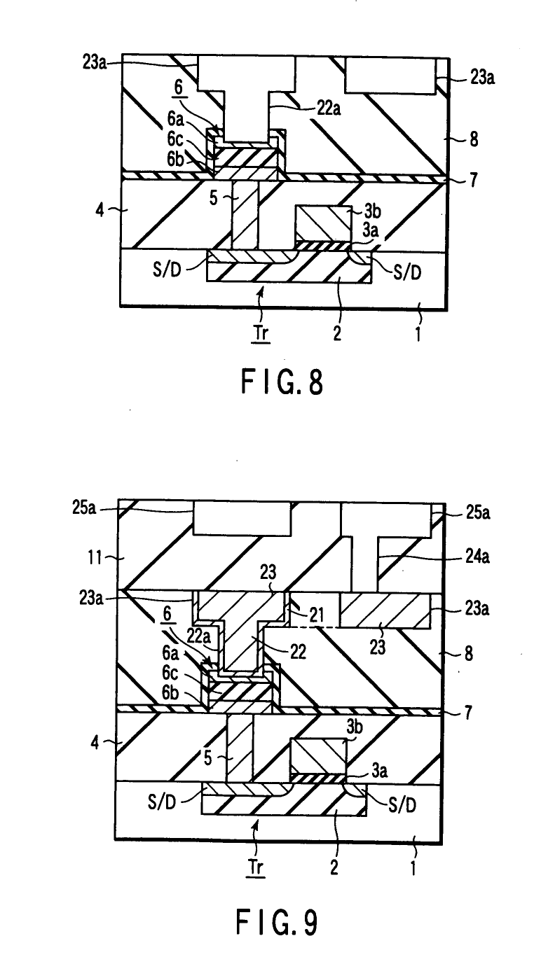

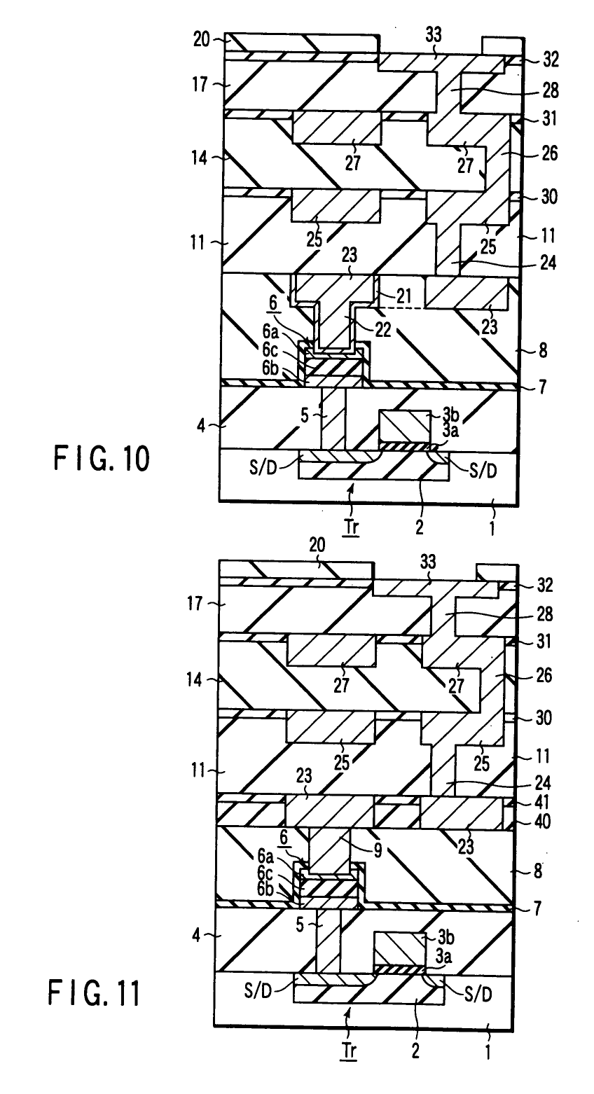

Now, with reference to FIGS. 8 and 9, description will be given of a manufacturing process for an FeRAM having the structure shown in FIG. 7. A manufacturing process executed before the protective film 7 is formed is similar to that in the first embodiment. Its illustration and description are omitted.

As shown in FIG. 8, the P—SiO₂ interlayer insulating film 8 is formed on the protective film by the plasma CVD method at a temperature of 380 to 400° C. The via hole 22a, leading to the upper electrode 6a, and the interconnect groove 23a, in which the Cu interconnect 23 is formed, are opened by, for example, a dual damascene method. In this case, a small groove is formed in the surface of the upper electrode 6a of the ferroelectric capacitor 6 because of over-etching occurring during the formation of the via hole 22a. Then, to recover the ferroelectric capacitor 6 damaged by the formation of the ferroelectric capacitor 6, the formation of the protective film 7, the formation of the P—SiO₂ interlayer insulating film 8, the dual damascene method, and the like, the substrate is subjected to oxygen annealing at a temperature of 600° C. for one hour.

Then, as shown in FIG. 9, TiN barrier metal 21 (with a thickness of, for example, 100 [nm]) is formed in the via hole 22a and interconnect groove 23a. Furthermore, a liner film (not shown) is formed on the surface of the barrier metal 21. Then, Cu is simultaneously buried in the via hole 22a and interconnect groove 23a to form the Cu via plug 22 and the Cu interconnect 23. In this case, Cu is buried in the upper electrode 6a of the ferroelectric capacitor 6. As a result, the Cu via plug 6 and the Cu interconnect 23 are formed. Subsequently, the surfaces of the P—SiO₂ interlayer insulating film 8 and Al via plug 9 are flattened by the CMP method.

Then, for example, SiOₓC_{y}, which has a dielectric constant of 2.7, is used to form the low-k interlayer insulating film 11 on the P—SiO₂ interlayer insulating film 8 and Cu interconnect 23 by the plasma CVD method at a temperature of 350° C. Then, for example, the dual damascene method is used to form, in the low-k interlayer insulating film 11, a via hole 24a leading to the Cu interconnect 23 and an interconnect groove 25a in which the Cu interconnect 25 is formed. Then, to recover the low-k interlayer insulating film 11 damaged by the formation of the via hole 24a and the interconnect groove 25a, the substrate is subjected to oxygen annealing at a temperature of 380° C. for 30 minutes. Then, Cu is buried in the via hole 24a and interconnect groove 25a to form a Cu via plug 24 and a Cu interconnect 25. Subsequently, the surfaces of the low-k interlayer insulating film 11 and Cu interconnect 25 are flattened by the CMP method.

The dual damascene method is similarly used to form a Cu via plug 26 and a Cu interconnect 27 in a third layer. Further, the Cu interconnect 27 and Cu via plug 26 in the third layer are formed similarly to the Cu interconnect 25 in the second layer. In this manner, an FeRAM is formed which as the structure shown in FIG. 7.

As described above in detail, the second embodiment produces effects similar to those of the first embodiment. Furthermore, when the barrier metal 21 has a film thickness of 100 [nm], it is possible to block hydrogen radicals or the like which are generated by a material gas during the formation of the insulating film 8. This further reduces damage to the ferroelectric capacitor 6.

Further, damage to the ferroelectric capacitor 6 during the deposition of Cu can be suppressed by forming the upper electrode 6a of the ferroelectric capacitor 6 of IrOₓ/SrRuO₃, SrRuO₃, or Sr(Ru₍₁₋ₓ₎Ti₍ₓ₎)O₃.

### Third Embodiment

In the embodiment in FIG. 7, the low-k interlayer insulating films 11, 14, 17, having lower densities, are sequentially stacked. It is thus necessary to consider the intrusion of hydrogen during a postprocess if only the passivation film 20 is provided on these interlayer insulating films 11, 14, and 17. Further, CMP is executed after the Cu interconnects 23, 25, and 27 have been deposited in the low-k interlayer insulating films 11, 14, 17, having lower densities. Consequently, the flattening step may be affected. This is improved by the third embodiment shown in FIG. 10. Specifically, the FeRAM is constructed by forming on the low-k interlayer insulating film, the P—SiO₂ film, having a higher film density than the low-k film.

FIG. 10 is a sectional view showing the structure of an FeRAM according to a third embodiment of the present invention. In this figure, the same portions as those in FIGS. 1 and 7 are denoted by the same reference symbols. Their description will is omitted.

A P—SiO₂ film 30, having a dielectric constant of 4.1, is formed on the low-k interlayer insulating film 11. The P—SiO₂ film 30 is composed of, for example, TEOS with a thickness of 100 [nm]. Further, the P—SiO₂ film 30 is formed by the plasma CVD method at a temperature of 380 to 400° C.

After the P—SiO₂ film 30 has been formed, the dual damascene method is used to form the via plug 24 and the Cu interconnect 25. The surfaces of the P—SiO₂ film 30 and Cu interconnect 25 are flattened by CMP. P—SiO₂ films 31 and 32 are similarly formed on the low-k film 14 in the third layer and on the low-k film 15 in the fourth layer. The dual damascene method is also used to form the via plug 26 and Cu interconnect 27 in the third layer and the via plug 28 and an electrode pad 33 in a fourth layer.

The P—SiO₂ films 30, 31, and 32 thus formed have higher film densities than the low-k films 11, 14, and 17, thus suppressing diffusion of hydrogen or water. This suppresses the intrusion of hydrogen radicals into the ferroelectric capacitor 6, the intrusion of hydrogen or the like from the passivation film 20, the intrusion of hydrogen during hydrogen sintering process, the intrusion of hydrogen from mold material during packaging, and so on.

Further, the P—SiO₂ films 30, 31, and 32, having higher film densities than the low-k film, are each formed at the same level as the corresponding one of the Cu interconnects 25, 27, and 33. This reduces the percentage of defective resulting from the CMP process for the Cu interconnects 25, 27, and 33.

As described above, according to the third embodiment, the P—SiO₂ films 30, 31, and 32, having higher film densities, are arranged on the low-k interlayer insulating films 11, 14, and 17. It is thus possible to block hydrogen or hydrogen radicals to further reduce damage to the ferroelectric capacitor 6. Further, the insulating films 30, 31, and 32, having higher film densities, are each formed at the same level as the corresponding one of the Cu interconnects 25, 27, and 33. This reduces the percentage of defective resulting from the CMP process for the Cu interconnects 25, 27, and 33.

In the third embodiment, the three layers, i.e. the P—SiO₂ films 30, 31, and 32 are inserted. However, of course, the FeRAM can be suppressed from being degraded by hydrogen, simply by, for example, arranging at least the P—SiO₂ film 32 immediately below the passivation film 20.

Further, the inserted insulating film is not limited to the SiO₂ film, but any insulator is applicable provided that it has a higher film density.

### Fourth Embodiment

According to a fourth embodiment, the interlayer insulating film of the first layer formed on the protective film 7 is formed of a P—SiO₂ film, a low-k film, and a P—SiO₂ film.

FIG. 11 is a sectional view showing the structure of an FeRAM according to the fourth embodiment of the present invention. In this figure, the same portions as those in FIGS. 1, 7, and 10 are denoted by the same reference symbols. Their description will is omitted.

The Al via plug 9 is buried in the P—SiO₂ interlayer insulating film 8 and is connected to the upper electrode 6a of the ferroelectric capacitor 6. A low-k film 40 is stacked on the surfaces of the P—SiO₂ interlayer insulating film 8 and Al via plug 9. Furthermore, a P—SiO₂ film 41 is formed on the surface of the low-k film 40. The P—SiO₂ film 41 is formed of, for example, TEOS with a thickness of 100 [nm].

A single damascene method is used to form the Cu interconnect 23 in the P—SiO₂ film 41 and the low-k film 40. The Cu interconnect 23 is formed to connect to the Al via plug 9. The surfaces of the P—SiO₂ film 41 and Cu interconnect 23 are flattened by CMP.

As described above in detail, the fourth embodiment can be provided with one more P—SiO₂ film than the third embodiment. This serves to block more hydrogen, hydrogen radicals, or the like. It is thus possible to further reduce damage to the ferroelectric capacitor 6. Furthermore, the insertion of the low-k film 40, which is not provided in the embodiment in FIG. 10, serves to increase the ratio of the low-k films to the whole interlayer insulating films. This makes it possible to reduce stress that may occur in the semiconductor substrate 1. Further, the polarization capacitance of the ferroelectric capacitor 6 can be improved by increasing the ratio of the low-k films to the whole interlayer insulating films.

### Fifth Embodiment

According to a fifth embodiment, an FeRAM is constructed by forming a double protective film on the ferroelectric capacitor 6.

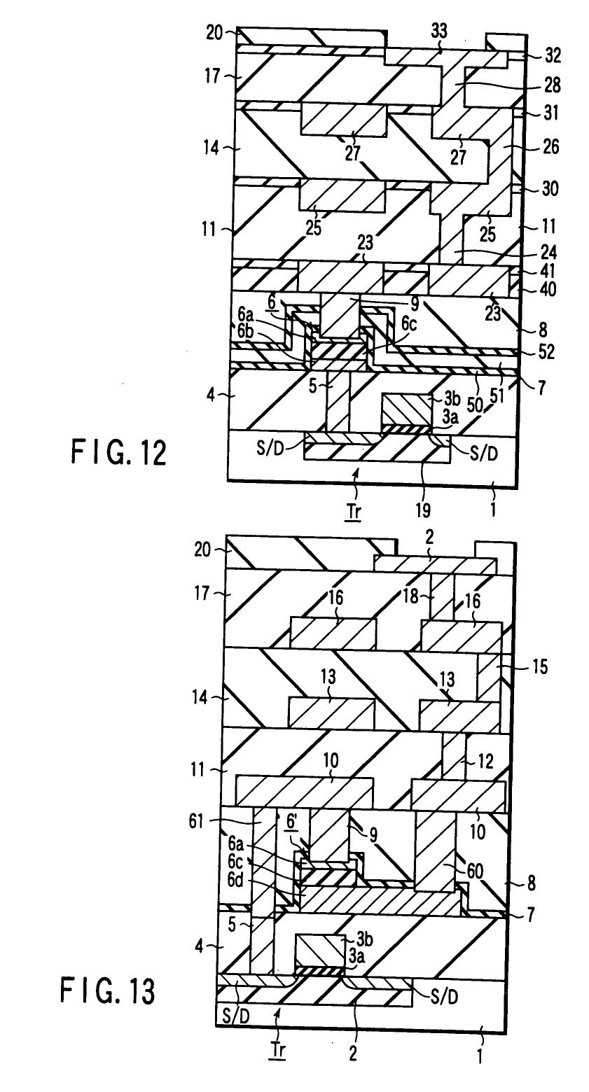

FIG. 12 is a sectional view showing the structure of an FeRAM according to the fifth embodiment of the present invention. In this figure, the same portions as those in FIG. 11 are denoted by the same reference symbols. Their description will is omitted.

A protective film 50 is formed on the surfaces of the ferroelectric capacitor 6 and insulating film 4 in order to prevent damage that may occur during the steps of manufacturing the multilayer interconnect layer. The protective film 50 is formed by, for example, carrying out sputtering or ALD to form a layer of aluminum oxide to a thickness of 50 [nm].

A P—SiO₂ film 51 (with a thickness of, for example, 50 [nm]) with a dielectric constant of 4.1 is formed on the protective film 50. The P—SiO₂ film 51 is composed of, for example, TEOS. A protective film 52 is formed on the P—SiO₂ film 51. The protective film 52 is formed by, for example, carrying out sputtering or ALD to form a layer of aluminum oxide to a thickness of 50 [nm].

As described above in detail, according to the fifth embodiment, the doubled protective film is formed on the P—SiO₂ films 30, 31, 32, and 41. This makes it possible to block effectively the intrusion of hydrogen, hydrogen radicals, or the like into the ferroelectric capacitor 6. It is thus possible to reduce damage to the ferroelectric capacitor 6.

By forming a double protective film as described above, hydrogen or hydrogen radicals can be sufficiently blocked even if the P—SiO₂ films 30, 31, 32, and 41 are not inserted.

### Sixth Embodiment

According to a sixth embodiment, an upper and lower electrodes of a ferroelectric capacitor 6′ have an offset structure. In this embodiment, an FeRAM is constructed by providing not only a via plug connected to the upper electrode but also a via plug connected to and formed on the lower electrode.

FIG. 13 is a sectional view showing the structure of an FeRAM according to the fifth embodiment of the present invention. In this figure, the same portions as those in FIG. 11 are denoted by the same reference symbols. Their description will is omitted.

A lower electrode 6d for the ferroelectric capacitor 6′ is wider than the upper electrode 6a so that an Al via plug 60 connected to the lower electrode 6d can be formed on the lower electrode 6d. Accordingly, the upper and lower electrodes 6a and 6d have an offset structure. The lower electrode 6d has a stacked structure of, for example, SrRuO₃/Pt/Ti or Pt/Ti.

The Al via plug 60 is buried in the P—SiO₂ interlayer insulating film 8 and is connected to the lower electrode 6d of the ferroelectric capacitor 6′. The Al via plug 60 is formed similarly to the Al via plug 9, connected to the upper electrode 6a.

Further, an Al via plug 61 is buried in the P—SiO₂ interlayer insulating film 8 and is connected to the contact plug 5. The Al via plug 61 is, for example, formed similarly to the Al via plug 9.

The Al interconnect 10 of the first layer is formed on the P—SiO₂ interlayer insulating film 8 so as to connect to the Al via plugs 9, 60, and 61. The Al interconnect 10 is formed by, for example, using RIE to pattern an Al film deposited on the P—SiO₂ interlayer insulating film 8.

As described above in detail, the sixth embodiment produces effects similar to those of the first embodiment even if the via plugs connected to the upper electrode 6a and the lower electrode 6d, respectively, are formed on the electrodes 6a and 6d, respectively.

Further, the Al interconnect 10 is formed by using the RIE method, thereby the characteristic of the ferroelectric capacitor 6′ has been improved.

Furthermore, the Al interconnects 13 and 16 are formed by using the RIE method, thereby the characteristic of the ferroelectric capacitor 6′ has been improved. And, FeRAM has the low-k interlayer insulating film and interconnect formed by the RIE method, thereby the characteristic of the ferroelectric capacitor 6′ has been improved.

Furthermore, even if the configuration of any of the second to fifth embodiments is applied to the offset structure of the ferroelectric capacitor described in the sixth embodiment, effects similar to those of the respective embodiments can be produced.

The embodiments employ aluminum oxide as the protect films 7 and 52. However, the protect films 7 and 52 is not limited to this, may be composed of at least one of AlₓO_{y}, ZrₓO_{y}, AlₓSi_{y}O_{z}, SiₓN_{y}, and TiₓO_{y}.

The embodiments employ Al or Cu as the interconnect material. However, the interconnect material is not limited to this, may be except for Al and Cu.

In the embodiments, the Al via plug may be formed by W or Cu.

This invention can be applied to an FeRAM structure which use another ferroelectric capacitor, for example a chain FeRAM which is proposed by Toshiba.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-20. (canceled)

21. A semiconductor device comprising:
a switching element provided in a semiconductor substrate;
a first level layer provided on the semiconductor substrate and including a first insulating layer and a first wiring layer electrically connected to one terminal of the switching element;
a ferroelectric capacitor provided on the first level layer and including a first electrode electrically connected to the one terminal of the switching element;
a first protective film provided on the ferroelectric capacitor and the first level layer;
a second level layer provided on the first protective film and including a second insulating layer and a second wiring layer, the second insulating layer having a dielectric constant of 4 or more, the second wiring layer being electrically connected to a second electrode of the ferroelectric capacitor; and
a third level layer provided on the second level layer and including a third insulating layer, a fourth insulating layer and a third wiring layer, the third insulating layer having a dielectric constant of less than 4, the fourth insulating layer being provided on the third insulating layer and having a dielectric constant of 4 or more, the third wiring layer being electrically connected to the second wiring layer.

22. The semiconductor device according to claim 21, wherein the second insulating layer and the fourth insulating layer contain SiO₂.

23. The semiconductor device according to claim 22, wherein the second insulating layer and the fourth insulating layer contain plasma SiO₂.

24. The semiconductor device according to claim 21, wherein the third insulating layer is formed of a low-k dielectric.

25. The semiconductor device according to claim 21, wherein the first protective film is a metal oxide.

26. The semiconductor device according to claim 25, wherein the first protective film is formed of a material selected from the group consisting of AlₓO_{y}, ZrₓO_{y}, AlₓSi_{y}O_{z}, and TiₓO_{y}.

27. The semiconductor device according to claim 21, wherein:
the second level layer includes a fifth insulating layer and a sixth insulating layer;
the fifth insulating layer is provided on the second insulating layer and has a dielectric constant of less than 4; and
the sixth insulating layer is provided on the fifth insulating layer and has a dielectric constant of 4 or more.

28. The semiconductor device according to claim 27, wherein;
the fifth insulating layer is formed of a low-k dielectric; and
the sixth insulating layer contains SiO₂.

29. The semiconductor device according to claim 28, wherein the sixth insulating layer contains plasma SiO₂.

30. The semiconductor device according to claim 21, wherein:
the second level layer includes a seventh insulating layer and a second protective film;
the seventh insulating layer is provided on the first protective film;
the second protective film is provided on the seventh insulating layer; and
the second insulating layer is provided on the second protective film.

31. The semiconductor device according to claim 30, wherein the seventh insulating layer has a dielectric constant of 4 or more.

32. The semiconductor device according to claim 31, wherein the seventh insulating layer contains SiO₂.

33. The semiconductor device according to claim 30, wherein the second protective film is a metal oxide.

34. The semiconductor device according to claim 33, wherein the second protective film is formed of a material selected from the group consisting of AlₓO_{y}, ZrₓO_{y}, AlₓSi_{y}O_{z}, and TiₓO_{y}.

35. The semiconductor device according to claim 21, wherein the second wiring layer and the third wiring layer contain a Cu-based material.

36. The semiconductor device according to claim 21, wherein the second wiring layer and the third wiring layer contain an Al-based material.
